(19) United States
(12) Patent Application Publication
(10) Pub. No.: US 2012/0027515 A1
(43) Pub. Date: Feb. 2, 2012

(54) SOLAR MODULE SYSTEM AND METHOD OF MAKING THE SAME

(76) Inventors: Timothy L. Neugent, Des Moines, IA (US); Brad Scandrett, Ames, IA (US)

(21) Appl. No.: 12/985,047

(22) Filed: Jan. 5, 2011

Related U.S. Application Data
(60) Provisional application No. 61/292,251, filed on Jan. 5, 2010.

(51) Int. Cl. B63C 3/06; H01L 31/048

(52) U.S. Cl. 405/3; 136/251

(57) ABSTRACT

A boat lift system that utilizes a solar module system. The solar module system includes a flexible solar film that is secured to a magnetic member that is electrically connected to a junction box. The junction box additionally is electrically connected to the electrical system of the boat lift such that electricity generated from the flexible solar film is transferred to the electrical system of the boat lift.

### CROSS REFERENCE TO RELATED APPLICATION

This application claims the benefit of U.S. Provisional Application No. 61/292,251 filed Jan. 5, 2010.

### BACKGROUND OF THE INVENTION

This invention is directed toward a solar module system for providing power to a vehicle lift and more particularly to providing power to a marine lift.

Presently, conventional lifts have a deep cell battery that actuates the lifting operation. This battery needs to be charged when its energy is depleted by the lift. As such, a need exists in the art for a system that is easily attached to a marine lift to provide charging of the electrical system of the lift and recharge the lift's battery. Thus, a principal object of the present invention is to provide a boat lift system that utilizes solar energy to recharge the lift's battery.

These and other features, advantages, and attributes will be discussed further in the specification and claims.

### BRIEF SUMMARY OF THE INVENTION

A boat lift system that includes a boat lift that has an electrical system that activates the boat lift. The boat lift system also has a solar module system that has a flexible solar film secured to a magnetic member. The solar module system also has a junction box that is electrically connected to the magnetic member and electrical system of the boat lift to transfer electricity from the flexible solar film to the electrical system of the lift.

### BRIEF DESCRIPTION OF THE DRAWINGS

FIG. 1 is a schematic diagram of a boat lift system;

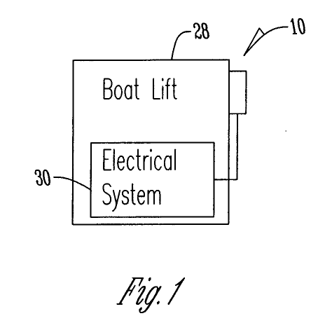

FIG. 2 is a side perspective view of a solar module system of a boat lift system.

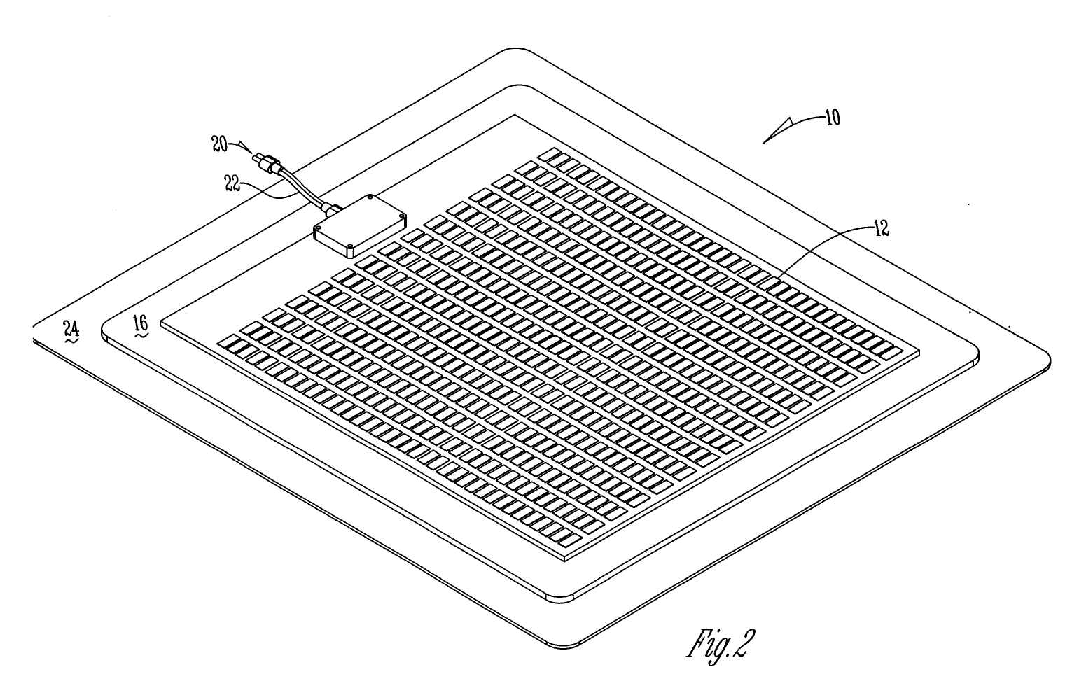

FIG. 3 is a side perspective view of solar module system of a boat lift system.

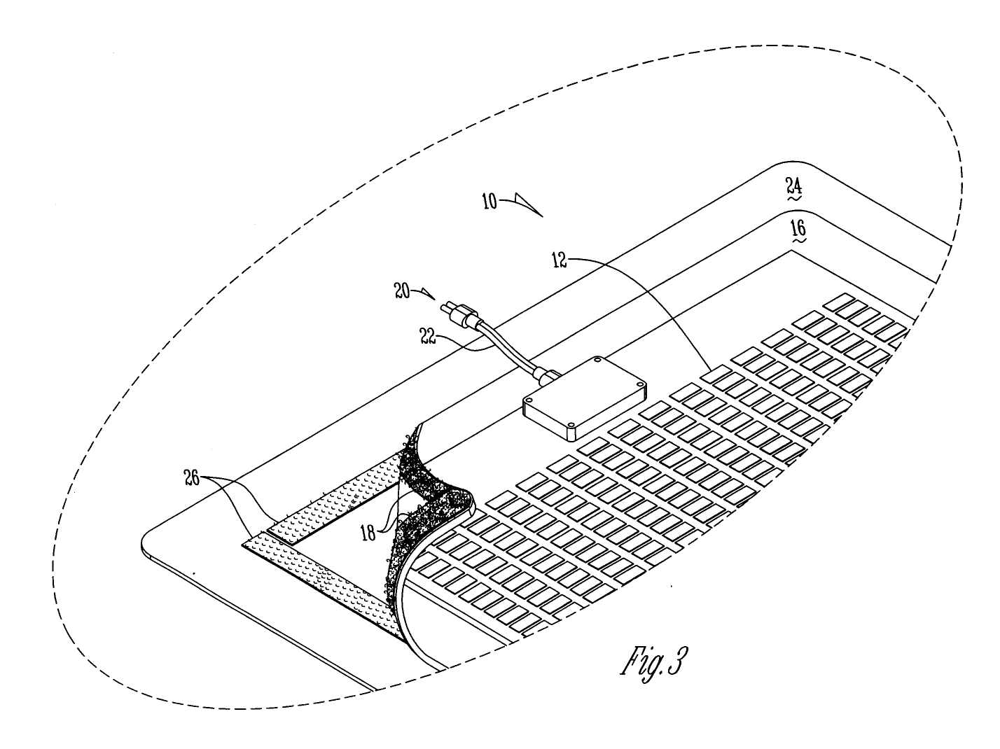

### DETAILED DESCRIPTION OF THE PREFERRED EMBODIMENT

Referring to the Figures, the system 10 has a solar film 12 such as a thin flexible layer of photovoltaic film having a monolithic integration. The solar film 12 is laminated, preferably through a vacuum lamination process, with a UV stable protective to encapsulate the film 12. In one exemplary example a protective encapsulate is placed on the top of the film and a thermal adhesive on the bottom which is connected to a first vinyl mat 16 below it such that the film 12 is sandwiched between the encapsulate and thermal adhesive.

Attachment devices are connected to the first vinyl mat 16 by any means known in the art such as by sewing, gluing, riveting crimping or the like. Attachment devices 18 are any device known in the art that connects one object to another such as Velcro®, buttons, zippers, magnets, snap fit devices, or the like. In a preferred embodiment Velcro® strips are sewn into the perimeter of the first vinyl mat 16 and surround the solar module 10. Finally a junction box 20 having a wire 22 which terminates in an electrical connector is attached to the first vinyl mat 16 or other part of the system through any conventional means such as rivets.

The system has a second mat 24 which is constructed of any material known in the art such as fabric, canvas, plastic, vinyl or the like. The second mat 24 has an adhesive back which is covered by a removable liner prior to installation. In one example butyl adhesive is used, however any other adhesive known in the art such as glue, epoxy, or the like is used. In a preferred embodiment the second mat 24 extends beyond the borders of the first mat 16 so as to provide a border of adhesive that resists delamination when attaching and removing the first mat 16. Alternatively, the second mat 24 is the same size or smaller than the first mat 16.

Connected to the second mat 24 by any means known in the art such as by sewing, gluing, riveting, crimping or the like are a plurality of connection devices 26. Connection devices 26 are any device know in the art that receive and removably connect to the attachment devices of the first mat such as Velcro, buttons, zippers, magnets, snap fit devices, or the like. The position of these connection devices 26 on the second mat 24 mirror the position of the attachment devices 18 on the first mat 16 so as to allow for easy attachment and separation of the first mat 16 and the second mat 24. In a preferred embodiment these connection devices 26 are Velcro strips which are sewn into the second mat 24.

Once assembled, the module 10 is attached to a marine lift 28 or the cover thereof and is connected to the electrical system 30 such as a battery or other main power supply. To attach the system to the lift 28, the application surface of the lift 28 is cleaned, preferably with an alcohol based cleaning solution. The liner is then peeled back exposing the adhesive and the second mat 24 is adhered to the lift's surface. Once attached, the junction box 20 is electrically connected to a device on the lift 28 such as the battery or main power supply.

Alternatively, in another embodiment, connection devices 26 are directly connected to the lift 28 itself or the cover thereof thereby obviating the need for the second mat 24 altogether. In yet another alternative embodiment, the solar film 12 of the first mat 16 is directly manufactured, formed or integrated into the lift or the lift's cover thereby obviating the need for a first mat which is then connected to the boat lift 28 as specified above.

The size and shape of the module 10 can be adapted for different applications. An advantage of the Power Pier module 10 is that it is easy to install and can be easily removed when not in use while obtaining sufficient solar power to charge the batteries on the lift. It can also be used to power other devices when not in use for the lift 28. From the above discussion it will be appreciated that the system presents a novel and useful device for charging the electrical system of a lift. Accordingly, the system provides and offers many advantages over the prior art.

It will be appreciated by those skilled in the art that other various modifications could be made to the device without parting from the spirit and scope of this invention. All such modifications and changes fall within the scope of the claims and are intended to be covered thereby. Thus, at least all of the objectives have been met.

What is claimed is:

1. A boat lift system comprising:
a boat lift having an electrical system that actuates the boat lift;
a solar module system having flexible solar film secured to a magnetic member; and
said solar module system further comprising a junction box electrically connected to the magnetic member and electrical system of the boat lift to transfer electricity from the flexible solar film to the electrical system of the boat lift.

2. The system of claim 1 wherein the flexible solar film is encapsulated with a UV stable protective encapsulate.

3. The system of claim 2 wherein the flexible solar film is adhered to a first mat with a thermal adhesive.

4. The system of claim 3 further comprising attachment devices connected to the first mat to secure the first mat to the boat lift.

5. The system of claim 4 wherein the attachment device is a strip of hook and loops.

6. The system of claim 4 further comprising a second mat that is adhered to the boat lift and having connection devices.

7. The system of claim 6 wherein the second mat extends beyond a border of the first mat to provide a border of adhesive that resists delamination when removing the first mat.

8. The system of claim 6 wherein the connecting devices of the second mat mate with the attachment devices of the first mat to secure the first mat to the second mat.

9. The system of claim 8 wherein the connection devices are a strip of hook and loops.
